(19) United States
(12) Patent Application Publication
(10) Pub. No.: US 2014/0284718 A1
(43) Pub. Date: Sep. 25, 2014

(54) METHOD OF REDUCION GRAPHENE OXIDE AND REDUCED GRAPHENE OXIDE OBTAINED BY THE METHOD, AND THIN FILM TRANSISTOR INCLUDING THE REDUCED GRAPHENE OXIDE

(71) Applicant: KOREA INSTITUTE OF SCIENCE AND TECHNOLOGY, Seoul (KR)

(72) Inventors: Jung Ah LIM, Gyeonggi-do (KR); Yong-Won SONG, Daejeon (KR); Jae-Min HONG, Seoul (KR); Joo Young CHANG, Seoul (KR)

(73) Assignee: KOREA INSTITUTE OF SCIENCE AND TECHNOLOGY, Seoul (KR)

(21) Appl. No.: 14/196,058

(22) Filed: Mar. 4, 2014

(30) Foreign Application Priority Data
Mar. 20, 2013 (KR) 10-2013-0029983

(51) Int. Cl. H01L 29/49; H01L 29/786; C01B 31/04

(52) U.S. Cl. CPC H01L 29/4908; C01B 31/043; H01L 29/786
USPC 257/347; 423/415.1; 428/195.1; 427/553

(57) ABSTRACT

Disclosed are a method of manufacturing a reduced graphene oxide pattern which includes forming a graphene oxide pattern on a substrate and providing the graphene oxide pattern with a white light pulse to reduce the graphene oxide, a reduced graphene oxide obtained by the method, and an electronic device and a thin film transistor including the reduced graphene oxide.

This application claims priority to and the benefit of Korean Patent Application No. 10-2013-0029983 filed in the Korean Intellectual Property Office on Mar. 20, 2013, the entire contents of which are incorporated herein by reference.

### BACKGROUND OF THE INVENTION

(a) Field of the Invention

A method of manufacturing a reducing graphene oxide, a reduced graphene oxide obtained by the method, and a thin film transistor including the reduced graphene oxide are disclosed.

(b) Description of the Related Art

In general, various electronic devices such as a display device, a light emitting diode, a solar cell, and the like form an image or generate electricity by transmitting light, and thus necessarily require a transparent conductive layer being capable of transmitting light. Indium tin oxide (ITO) has been widely used to form such a transparent conductive layer.

However, as the indium tin oxide becomes expensive due to increasing consumption of indium, economy may be deteriorated, and in particular, since the transparent conductive layer including the indium has a chemical and electrical defect, an alternative transparent conducting material is required.

Accordingly, graphene is being paid attention to as a transparent conducting material. The graphene is a one atom-thick material having a honeycomb-shaped carbon lattice and is drawing attention as an essential material applicable to a next generation device such as a semiconductor device, a solar cell, a supercapacitor, a flexible display, and the like due to high electrical conductivity and transparency.

The graphene is manufactured by exfoliating a massive amount of graphite into pieces to obtain nano-graphite that is close to a single layer using a chemical or mechanical method. The manufacturing method may massively produce graphene having a uniform liquid colloid phase which may be applied to various solution processes.

In particular, the graphene may be transformed since a functional group easily causing a reaction is introduced into a graphene oxide. However, the graphene oxide may be reduced into graphene by heat-treating the graphene oxide under a reduction atmosphere at a high temperature or by using an environmentally-harmful reducing agent such as hydrazine.

### SUMMARY OF THE INVENTION

One embodiment provides an environmentally friendly, fast, and simplified method of manufacturing a reduced graphene oxide pattern.

Another embodiment provides a reduced graphene oxide pattern obtained by the method.

Yet another embodiment provides a thin film transistor including the reduced graphene oxide pattern.

A method of manufacturing a reducing graphene oxide according to one embodiment includes forming a graphene oxide on a substrate, and providing the graphene oxide with a white light pulse to reduce the graphene oxide.

The process of forming the graphene oxide may include preparing a graphene oxide solution, and applying the graphene oxide solution to a substrate.

The process of applying the graphene oxide solution may be performed in a method of inkjet printing, slit printing, or a combination thereof.

The process of preparing the graphene oxide solution is performed by dispersing a graphene oxide into water, and adding a solvent to the dispersion.

The graphene oxide may be dispersed in a concentration of about 0.1 to about 1.0 wt %.

The solvent may include N-methylpyrrolidone (NMP), dimethylpyrrolidone, ethylene glycol, acetone, tetrahydrofuran, acetonitrile, dimethylformamide, methanol, ethanol, propanol, or a combination thereof.

The solvent may be added in an amount of about 30 to about 80 wt % based on the total amount of the dispersion.

The process of supplying the white light pulse with the graphene oxide may be performed with a pulse duration of about 1 ms to about 500 ms.

The process of supplying the white light pulse with the graphene oxide may be performed with a pulse pause of about 0.1 ms to about 500 ms.

The process of supplying the white light pulse with the graphene oxide may be performed by radiating the white light pulse with an energy amount of about 5 to about 200 J/cm².

The process of supplying the white light pulse with the graphene oxide may be performed by radiating the white light pulse about once to a hundred times.

The process of supplying the white light pulse to the graphene oxide may be performed by radiating the white light pulse about three times to about twenty times.

The substrate may include silicon, glass, an oxide, a nitride, a plastic, or a combination thereof.

According to another embodiment, a reduced graphene oxide obtained by the method is provided.

The reduced graphene oxide may be patterned to have a width of about 20 μm to about 300 μm.

According to another embodiment, an electronic device including the reduced graphene oxide is provided.

Yet another embodiment provides a thin film transistor including a gate electrode, a semiconductor overlapped with the gate electrode, and source and drain electrodes electrically connected to the semiconductor and facing each other in the center of the semiconductor, wherein the source and drain electrodes include the reduced graphene oxide.

The thin film transistor may further include a gate insulating layer positioned between the gate electrode and the semiconductor.

An environmentally friendly, fast, and simplified method of reducing a graphene oxide without using a chemical solution such as a reducing agent and without a separate patterning process such as photolithography, and a reduced graphene oxide having high electrical conductivity and a device including the reduced graphene oxide, may be provided.

### BRIEF DESCRIPTION OF THE DRAWINGS

FIGS. 1 to 3 are schematic views showing a method of reducing a graphene oxide according to one embodiment,

FIG. 4 is a cross-sectional view showing a thin film transistor according to one embodiment,

FIG. 5 (a) is an XPS graph showing a graphene oxide before radiating a white light pulse,

FIG. 5 (b) is an XPS graph showing a reduced graphene oxide after radiating a white light pulse,

FIG. 6 is a graph showing current characteristics of a reduced graphene oxide pattern according to Example 1 depending on a voltage,

FIG. 7 is a graph showing current characteristics of reduced graphene oxide patterns according to Examples 1 and 2,

FIG. 8 is a graph showing conductivity of the reduced graphene oxide patterns according to Examples 1 and 2 depending on a radiation frequency,

FIG. 9 is a graph showing current characteristics (I_{DS}-V_{DS}) of a thin film transistor according to Example 3,

FIG. 10 is a graph showing current characteristics (I_{DS}-V_{DS}) of a thin film transistor according to Example 4, and

FIG. 11 is graph showing transference characteristics of the thin film transistor according to Example 4.

### DETAILED DESCRIPTION

Exemplary embodiments of the present invention will hereinafter be described in detail, and may be easily performed by those who have common knowledge in the related art. However, this disclosure may be embodied in many different forms, and is not construed as limited to the exemplary embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Hereinafter, a method of manufacturing a reducing graphene oxide according to one embodiment is illustrated with reference to the drawings.

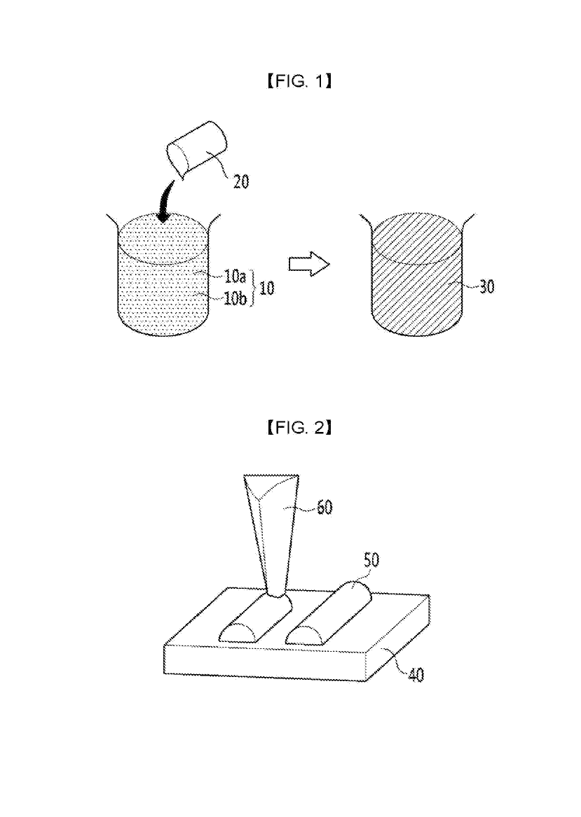

FIGS. 1 to 3 are schematic views showing a method of reducing a graphene oxide according to one embodiment.

First of all, referring to FIG. 1, a graphene oxide solution 30 is prepared.

The preparation of the graphene oxide solution 30 includes dispersing a graphene oxide 10b in water 10a and adding a solvent 20 to a resultant dispersion 10.

The graphene oxide 10b may be obtained, for example, by pulverizing graphite into powder, reducing the powder with an oxidant such as potassium permanganate (KMnO₄), and ultrasonicating the powder for separation.

The dispersion of the graphene oxide 10b may be performed by adding the graphene oxide 10b to the water 10a and ultrasonicating the mixture. Herein, the graphene oxide 10b may be dispersed in a concentration of about 0.1 to about 1.0 wt %. When the graphene oxide 10b is concentrated within the concentration range, various solution processes may be adopted to form a layer.

Subsequently, the solvent 20 is added to the dispersion 10. The solvent 20 has no particular limit as long as the dispersion is uniformly dissolved therein, but may include, for example, N-methylpyrrolidone (NMP), dimethylpyrrolidone, ethylene glycol, acetone, tetrahydrofuran, acetonitrile, dimethylformamide, methanol, ethanol, propanol, or a combination thereof. The solvent may improve morphology of a graphene oxide pattern by stably discharging the graphene oxide solution in the post-described solution process.

The solvent 20 may be included in an amount of about 10 to about 80 wt % based on the total amount of the dispersion 10. When the solvent is included within the range, a graphene oxide pattern having morphology of a uniform thickness may be obtained.

Referring to FIG. 2, a graphene oxide pattern 50 is formed on a substrate 40.

The substrate 40 may include, for example silicon, glass, an oxide, a nitride, or a combination thereof. The substrate 40 may be, for example, a silicon wafer.

The graphene oxide pattern 50 is formed by applying a graphene oxide solution 30 on the substrate 40 in a method of, for example, inkjet printing, slit printing, or a combination thereof. Herein, the printing may be performed by using a dispenser 60 having a nozzle, and the dispenser 60 may be, for example, a microfluidic dispenser. During the printing, a pattern may be formed by contacting a droplet on a substrate after controlling a meniscus generated in the nozzle by controlling transformation of a piezoelectric element.

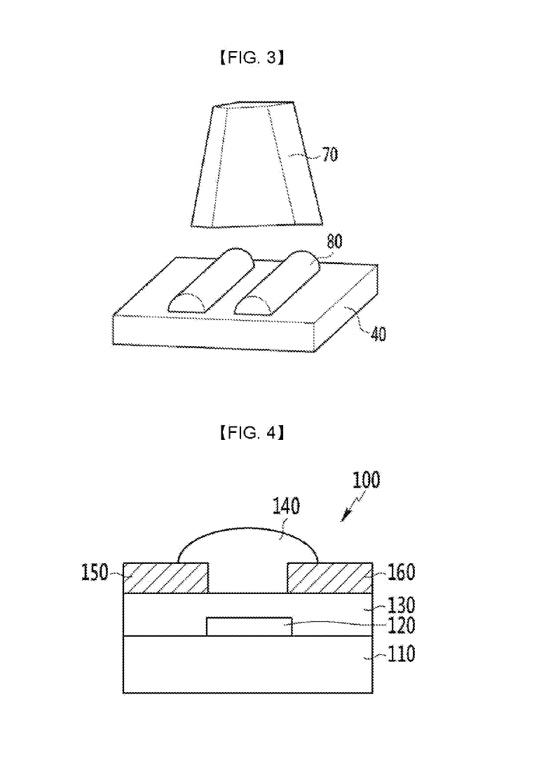

Referring to FIG. 3, a reduced graphene oxide pattern 80 is formed by radiating a white light pulse 70 to the graphene oxide pattern 50. The white light pulse 70 may be, for example, an intense pulsed light (IPL).

The white light pulse 70 may consist of, for example, a xenon flash lamp, a triggering/controlling circuit, a capacitor, a reflection mirror, a light wavelength filter, and the like.

The xenon flash lamp is housed in a lamp housing equipped with a quartz tube and a cooler for cooling the lamp by using cool water and a path for supplying the cooler with the cool water.

The light wavelength filter may selectively filter a predetermined wavelength region, and may vary depending on kinds and size of a particle and kinds and size of a substrate.

In addition, the lamp housing is equipped with a vertical distance controller, a horizontal substrate-moving device such as a conveyor belt, an assistant heating plate, an assistant cooling plate, a beam guide, and the like.

The vertical distance controller may adjust a distance between the xenon flash lamp and the substrate, and the horizontal substrate-moving device such as a conveyor belt may make a real time process possible. The assistant heating plate and/or assistant cooling plate are equipped in the conveyor belt, and may improve efficiency and quality of a sintering process. The beam guide may precisely control the direction of light, and may be made of, for example, quartz.

The white light pulse 70 may be adjusted by controlling necessary conditions, for example, a pulse duration, a pulse off-time, the number of pulses, peak intensity of a pulse, average pulse energy, and the like.

For example, the white light pulse 70 may be radiated with pulse energy of about 5 to about 200 J/cm², and herein, the pulse may last for about 1 ms to 500 ms and be paused for about 0.1 to about 500 ms. The white light pulse 70 may have a number of pulses of about 1 to about 99 per unit time.

The white light pulse 70 may be radiated once or more than once, and conductivity may be controlled depending on the number of radiations. For example, the white light pulse 70 may be radiated about 1 to about 99 times, specifically, about 1 to about 50 times, and more specifically about 3 to about 20 times within the range.

The radiation of the white light pulse 70 releases an oxygen atom and/or a hydroxyl group in the graphene oxide pattern 50, obtaining the reduced graphene oxide pattern 80.

The reduced graphene oxide pattern 80 may be a fine pattern having a width of about 20 to about 300 μm.

The white light pulse 70 may form a micron-sized fine pattern in a short time. In addition, the white light pulse 70 uses no chemical solution such as a reducing agent and thus has no influence on a lower layer or a neighboring pattern, or on a channel when used for an electrode of a thin film transistor, and resultantly, may realize satisfactory transistor characteristics.

The reduced graphene oxide pattern 80 may have high electrical conductivity, charge mobility, and transparency, like graphene. For example, the reduced graphene oxide pattern 80 may have transparency of about 70 to about 90%, sheet resistance of about 10 to about 100 kΩ, and electrical conductivity of about 0.1 to about 15 S/cm.

The reduced graphene oxide pattern 80 may be applied as an electrode of an electronic device due to the above high electrical conductivity, charge mobility, and transparency.

Hereinafter, a thin film transistor as one example of an electronic device is illustrated.

FIG. 4 is a cross-sectional view showing a thin film transistor according to one embodiment.

Referring to FIG. 4, a thin film transistor 100 according to one embodiment includes a substrate 110, a gate electrode 120 formed on the substrate 110, a gate insulating layer 130 formed on the gate electrode 120, a semiconductor 140 formed on the gate insulating layer 130, and a source electrode 150 and a drain electrode 160 formed on the gate insulating layer 130 and electrically connected to the semiconductor 140 and facing each other with the semiconductor 140 therebetween.

The substrate 110 may be formed of transparent glass, plastic, silicon, or the like. When the substrate 110 is conductive, the substrate 110 may play a role of a gate electrode.

The gate electrode 120 is connected to a gate line (not shown) transferring a gate signal. The gate electrode 120 is covered with the gate insulating layer 130, the gate insulating layer 130 may be formed of an inorganic insulation material such as a silicon oxide, a silicon nitride, or a combination thereof, or an organic insulation material such as polyvinylphenol.

The semiconductor 140 is formed of an inorganic semiconductor material such as silicon (Si) or an organic semiconductor material such as a monomer or oligomer, or a polymer having a structure that easily transfers electrons such as a conjugated system.

The organic semiconductor may be selected from, for example, a derivative including a substituent of tetracene or pentacene, an oligothiophene having 4 to 8 rings linked through positions 2 and 5 of a thiophene ring, polythienylenevinylene, poly-3-hexylthiophene, phthalocyanine, thiophene, or the like, but is not limited thereto.

The source electrode 150 and the drain electrode 160 may have the above reduced graphene oxide pattern. After forming the graphene oxide pattern as described above, the reduced graphene oxide pattern may be formed by supplying the graphene oxide pattern with a white light pulse and reducing the graphene oxide pattern, and accordingly, a micron-sized fine pattern may be formed without a particular patterning process like photolithography to have high electrical conductivity, charge mobility, and transparency.

A thin film transistor consists of one gate electrode 120, one source electrode 150, and one drain electrode 160 along with the semiconductor 140, and a channel of the thin film transistor is formed in the semiconductor 140 between the source electrode 150 and the drain electrode 160.

Hereinafter, the embodiments are illustrated in more detail with reference to examples and comparative examples. These examples, however, should not in any sense be interpreted as limiting the scope of the present invention.

### EXAMPLE 1

### Preparation of Graphene Oxide Solution

25 mg of graphene oxide is obtained by oxidizing 1 g of graphite powder (Sigma Aldrich Co., Ltd.) with 5 g of potassium permanganate (KMnO₄). Subsequently, 50 mg of the graphene oxide is added to 3 ml of water and the mixture is ultrasonicated, preparing a graphene oxide dispersion. Thereafter, 6 mL of n-methylpyrrolidone (NMP) is added to the graphene oxide dispersion and the mixture is agitated, preparing a graphene oxide solution.

### Formation of Reduced Graphene Oxide Pattern

The graphene oxide solution is then deposited in a dropwise fashion on a silicon wafer with a microfluidic dispenser to print a plurality of graphene oxide patterns having a width of 120 μm. Subsequently, the silicon wafer is disposed inside a globe box, and reduced graphene oxide patterns are formed by radiating 50 white light pulses with an energy amount of 60 J/cm² for 6 ms of on-time and 5 ms of off-time on the graphene oxide patterns.

### EXAMPLE 2

A reduced graphene oxide pattern is formed under the same conditions as in Example 1, except for changing the number of radiation shots of the white light pulse to two, three, five, ten, and twenty.

### Evaluation 1

The reduced graphene oxide pattern of Example 1 is analyzed by using x-ray photoelectron spectroscopy (XPS).

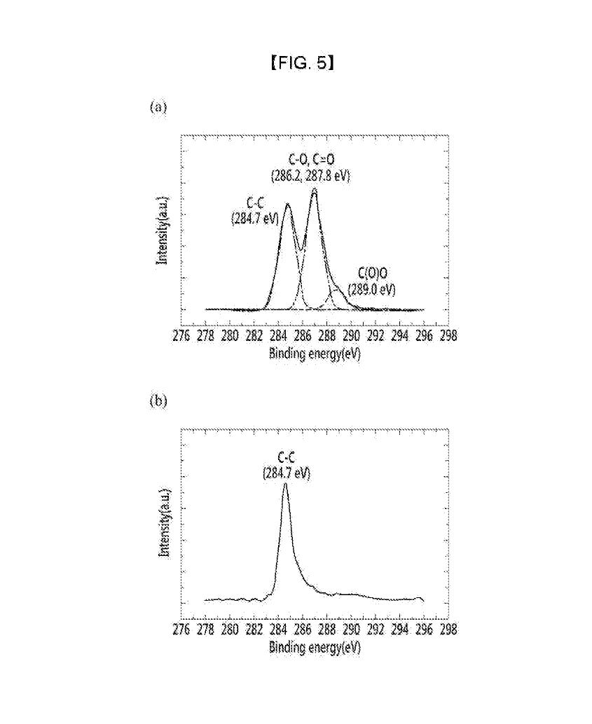

FIG. 5 (a) is an XPS graph showing the graphene oxide before radiation of the white light pulse, and FIG. 5 (b) is an XPS graph showing the reduced graphene oxide after radiation of the white light pulse.

Referring to FIG. 5, the graphene oxide before radiation of the white light pulse shows peaks of bonding energy (C—C) of about 284.7 eV, bonding energy (C—O) of about 286.2 eV, bonding energy (C═O) of about 287.8 eV, and bonding energy (C(O)O) of 289.0 eV, but the reduced graphene oxide after radiation of the white light pulse shows only a peak of bonding energy (C—C) of about 284.7 eV.

Accordingly, the graphene oxide is reduced by radiating white light pulses.

### Evaluation 2

Conductivity change of the reduced graphene oxide patterns according to Examples 1 and 2 is evaluated depending on the number of printing layers.

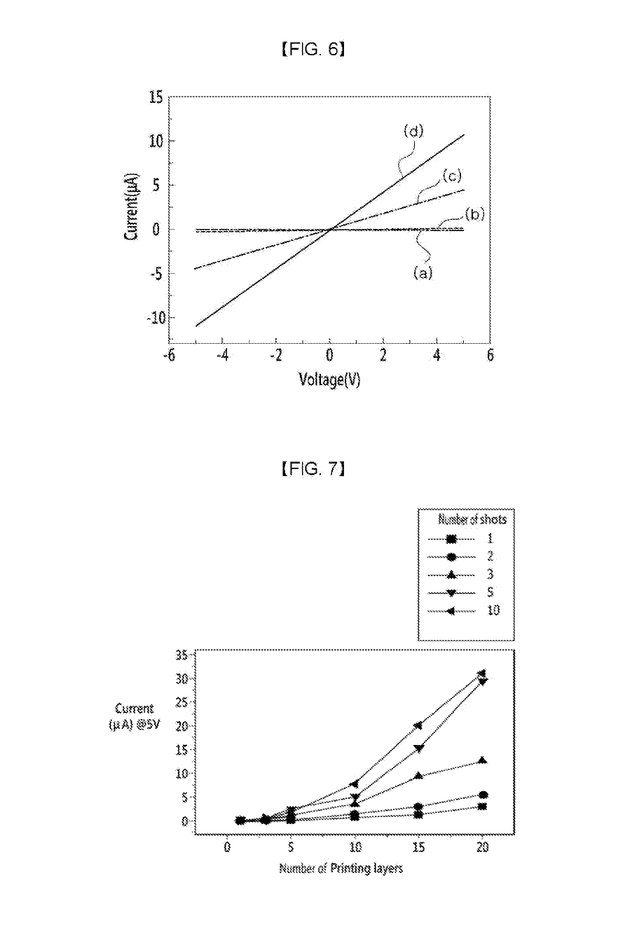

FIG. 6 is a graph showing current characteristics of the reduced graphene oxide pattern according to Example 1 depending on a voltage, and FIG. 7 is a graph showing current characteristics of the reduced graphene oxide patterns according to Examples 1 and 2 with regard to the number of printing layers.

Referring to FIG. 6, when the number of printing layers of the reduced graphene oxide pattern according to Example 1 is increased from one (a) to two (b), five (c), and ten (d), the current is increased.

Referring to FIG. 7, as the reduced graphene oxide patterns according to Examples 1 and 2 are printed more times, the current is increased. In addition, a reduced graphene oxide pattern that receives more radiation shots by a white light pulse shows higher current characteristics.

### Evaluation 3

Conductivity change of the reduced graphene oxide patterns according to Examples 1 and 2 is evaluated depending on a number of radiation shots.

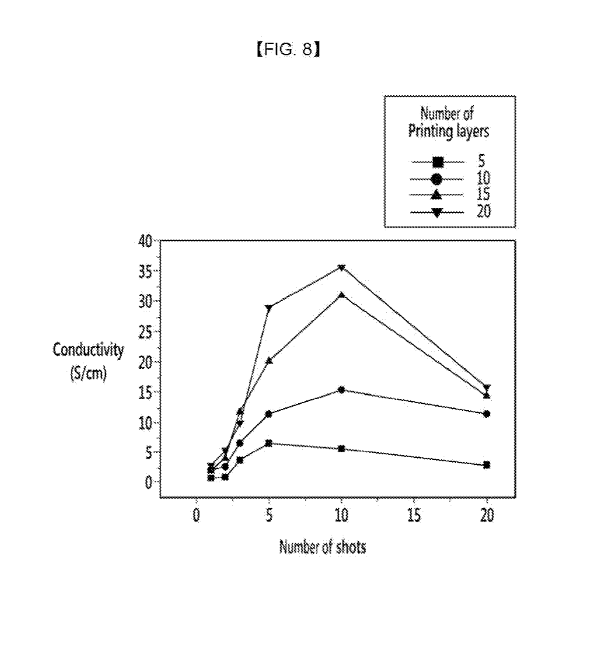

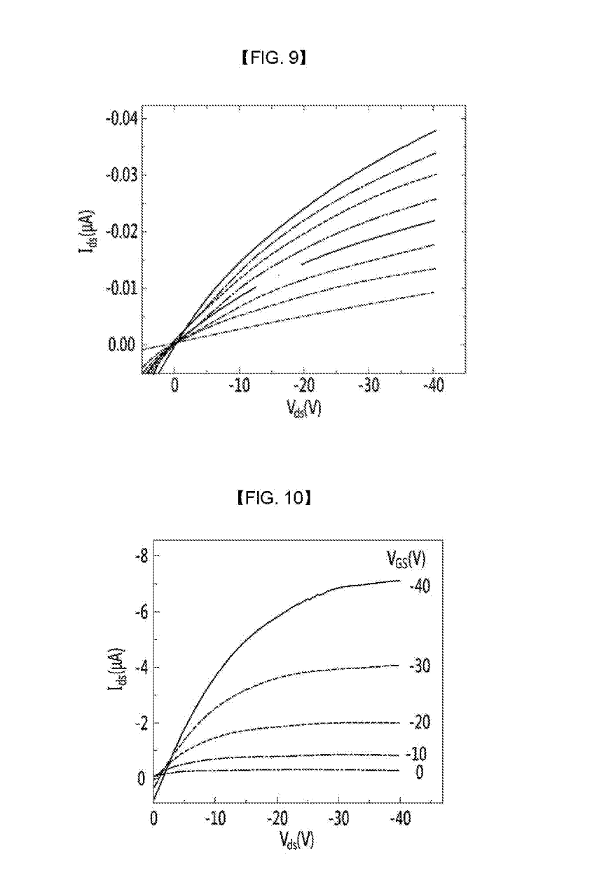

FIG. 8 is a graph showing conductivity of the reduced graphene oxide patterns according to Examples 1 and 2 depending on a number of radiation shots.

Referring to FIG. 8, the conductivity of the reduced graphene oxide pattern according to Examples 1 and 2 is changed depending on a number of radiation shots. Accordingly, the conductivity of the reduced graphene oxide patterns is adjusted by controlling the number of radiation shots.

### EXAMPLE 3

### Manufacture of Thin Film Transistor 1

Silicon oxide (SiO₂) is deposited to be 300 nm thick on a silicon substrate doped in a high concentration. The graphene oxide solution according to Example 1 is deposited at a predetermined interval with a microfluidic dispenser to form a graphene oxide pattern. Subsequently, the graphene oxide pattern is radiated by 50 pulses of a white light pulse for an on-time of 6 ms and an off-time of 5 ms with an energy amount of 60 J/cm², forming source and drain electrodes formed of the reduced graphene oxide. Poly(3-hexylthiophene) (P3HT) is then inkjet-printed on the source and drain electrodes and dried, manufacturing a thin film transistor.

### Evaluation 4

Current characteristics of the thin film transistor according to Example 3 are evaluated.

FIG. 9 is a graph showing current characteristics (I_{DS}-V_{DS}) of the thin film transistor according to Example 3.

Referring to FIG. 9, the thin film transistor according to Example 3 has satisfactory current characteristics depending on a voltage.

### EXAMPLE 4

### Manufacture of Thin Film Transistor 2

A thin film transistor is manufactured according to the same method as Example 3, except for using pentacene instead of the poly(3-hexylthiophene) (P3HT).

### Evaluation 5

Current characteristics of the thin film transistor according to Example 4 were evaluated.

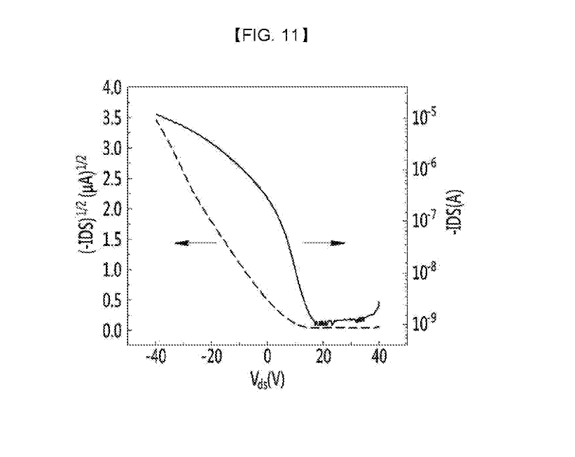

FIG. 10 is a graph showing current characteristics (I_{DS}-V_{DS}) of the thin film transistor according to Example 4, and FIG. 11 is a graph showing charge mobility characteristics of the thin film transistor according to Example 4. Referring to FIG. 10, the thin film transistor according to Example 4 shows satisfactory current characteristics depending on voltage, and referring to FIG. 11, the thin film transistor according to Example 4 shows charge mobility of 0.07 cm²N and a current ratio (Iₒₙ/I_{off}) of 10⁴.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of forming a reduced graphene oxide comprising:
forming a graphene oxide on a substrate; and
providing the graphene oxide with a white light pulse to reduce the graphene oxide.

2. The method of claim 1, wherein the formation of the graphene oxide comprises:
preparing a graphene oxide solution; and
applying the graphene oxide solution to a substrate.

3. The method of claim 2, wherein the application of the graphene oxide solution uses inkjet printing, slit printing, or a combination thereof.

4. The method of claim 2, wherein the preparation of the graphene oxide solution comprises:
dispersing a graphene oxide into water; and
adding a solvent to the dispersion.

5. The method of claim 4, wherein the graphene oxide is included in a concentration of about 0.1 to about 1.0 wt %.

6. The method of claim 4, wherein the solvent comprises N-methylpyrrolidone (NMP), dimethylpyrrolidone, ethylene glycol, acetone, tetrahydrofuran, acetonitrile, dimethylformamide, methanol, ethanol, propanol, or a combination thereof.

7. The method of claim 4, wherein the solvent is included in an amount of about 30 to about 80 wt % based on the total amount of the dispersion.

8. The method of claim 1, wherein the graphene oxide is supplied with the white light pulse for an on-time of about 1 ms to about 500 ms.

9. The method of claim 1, wherein the graphene oxide is supplied with the white light pulse for an off-time of about 0.1 msec to about 500 msec.

10. The method of claim 1, wherein the graphene oxide is supplied with the white light pulse with an energy amount of about 5 to about 200 J/cm².

11. The method of claim 1, wherein the graphene oxide is supplied with the white light pulse about 1 to about 100 times.

12. The method of claim 11, wherein the graphene oxide is supplied with the white light pulse about 3 to about 20 times.

13. The method of claim 1, wherein the substrate comprises silicon, glass, an oxide, a nitride, a plastic, or a combination thereof.

14. A reduced graphene oxide obtained according to claim 1.

15. The reduced graphene oxide of claim 14, wherein the reduced graphene oxide has a width of about 20 μm to about 300 μm.

16. An electronic device comprising the reduced graphene oxide of claim 14.

17. A thin film transistor comprising:
a gate electrode;
a semiconductor overlapped with the gate electrode; and
a source electrode and a drain electrode electrically connected to the semiconductor and facing each other in the center of the semiconductor,
wherein the source electrode and the drain electrode comprise the reduced graphene oxide of claim 14.

18. The thin film transistor of claim 17, further comprising a gate insulating layer between the gate electrode and the semiconductor.
